(19) United States
(12) Patent Application Publication
(10) Pub. No.: US 2025/0141245 A1
(43) Pub. Date: May 1, 2025

(54) Holder for a Charging Gun and Charging Device with a Holder for a Charging Gun

(71) Applicant: ABB E-mobility B.V., Delft (NL)

(72) Inventor: Marcin Cieciorko, Kraków (PL)

(73) Assignee: ABB E-mobility B.V., Delft (NL)

(21) Appl. No.: 18/926,539

(22) Filed: Oct. 25, 2024

(30) Foreign Application Priority Data
Oct. 26, 2023 (EP) 23206279.4

(51) Int. Cl. H02J 7/00; H05K 5/02

(52) U.S. Cl. CPC H02J 7/0042; H05K 5/023

(57) ABSTRACT

A holder for a charging gun includes a housing configured for receiving an end portion of a charging gun such that connector pins located at the end portion of the charging gun are completely covered by the housing of the holder, a protecting means configured for holding the charging gun in a designated position, and a connecting means that is configured for attaching the housing to a cable.

### CROSS-REFERENCE TO RELATED APPLICATIONS

The instant application claims priority to European Patent Application No. 23206279.4, filed Oct. 26, 2023, which is incorporated herein in its entirety by reference.

### FIELD OF THE DISCLOSURE

The present invention relates to a holder for a charging gun, in particular to combined charging system (CCS) or CCS-2 charging gun type, and to a device with a holder for a charging gun.

### BACKGROUND OF THE INVENTION

In application such as bus depos, tracks parking's, cars parking's or garage's, where the CCS or CCS-2 distribution box is mounted height above the ground (up to 6 m) and the charging cable with the charging gun freely hang out to the ground. There is a need to protect and service the charging gun. The plug mounted at the end of the charging gun has no cover therefore the connector pins are exposed to external environment conditions such as dust, water drops and moisture. Also in the situation where the cable is longer than the distance from distribution box to the ground, the cable will simple lie on the ground. Therefore there is need to protect the connector pins from external conditions and to service of the excess of the cable.

### BRIEF SUMMARY OF THE INVENTION

According to a first example of the disclosure a holder for a charging gun, comprises a housing configured for receiving an end portion of a charging gun, preferably CCS or CCS-2 type such that connector pins located at the end portion of the charging gun are totally covered by the housing of the holder, a protecting device or means, configured for holding the charging gun in a designated position, and a connecting device or means that is configured for attaching the housing to a cable.

Preferably, the protecting means is in a form of a blocking pin with a handle, wherein the handle is located on the outer side of the housing. The housing may be configured for receiving the charging gun in the housing by press-fitting.

Preferably, the protecting means is in a form of a hook attached to the housing, configured for engaging the hook with a corresponding protrusion on the surface of the charging gun. The housing may be made of a non-conductive material such as a polymer.

The holder may be inclined relative to the cable at an angle of less than 90°, and may comprise an adapter configured for aligning the position of the charging gun inside the housing. The adapter may be in the form of a grid.

Preferably, the connecting means is in the form of an element configured for attaching it to the housing in such a way that it is rigidly attached to the cable.

According to a second example of the disclosure a device with a charging gun and a cable comprising a holder.

### BRIEF DESCRIPTION OF THE SEVERAL VIEWS OF THE DRAWING(S)

FIG. 1 is a partial outline view of a holder in accordance with the disclosure.

FIG. 2 is a partial view of a device with a cable comprising a holder for the charging gun.

### DETAILED DESCRIPTION OF THE INVENTION

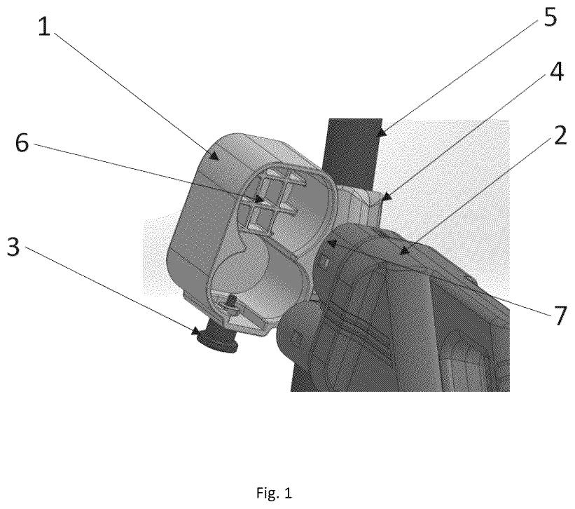

A holder for a charging gun is presented in details in FIG. 1. It comprises a housing 1 configured for receiving an end portion 7 of a charging gun 2, preferably CCS or CCS-2 type, such that connector pins located at the end portion 7 of the charging gun 2 are totally covered by the housing 1 of the holder. Such housing 1 enables protection of connector pins from environment conditions such as dust, water drops and moisture.

The holder also comprises a protecting means 3, configured for holding the charging gun 2 in a designated position. Such protecting means 3 prevents charging gun from being accidentally pulled out from the housing 1.

Moreover, the holder comprises a connecting means 4 that is configured for attaching the housing 1 to a cable 5. The holder can be thus stably connected to the cable at a desired height, preferably up to 6 m.

According to an embodiment of the disclosure, the protecting means 3 is in a form of a blocking pin with a handle, wherein the handle is located on the outer side of the housing 1. Holding the charging gun in one hand and the handle of blocking pin in other we are shifting the charging gun into to the housing of the gun holder. By releasing the handle of blocking pin the position of charging gun will be fixed. The blocking pin jumps to the hole in the CCS (CCS-2) plug slot.

According to the second embodiment, the housing 1 is configured for receiving the charging gun 2 in the housing 1 by press-fitting. This ensures tight and stable placement of the charging gun 2 in the holder.

According to the third aspect of the invention, the protecting means 3 is in a form of a hook attached to the housing 1, configured for engaging the hook with a corresponding protrusion on the surface of the charging gun 2.

Preferably the housing 1 is made of a non-conductive material. This increases safety of the users and people gathered around the holder and also increases safety of the place in which the charging station is mounted.

Preferably, the housing 1 is made of a polymer.

Preferably, the holder is inclined relative to the cable 5 at an angle of less than 90°. This causes, that the water from the rain or any other pollutions do not stay on the surface of the housing 1 but drops to the ground.

Preferably, it comprises an adapter 6 configured for aligning the position of the charging gun 2 inside the housing 1. This causes that the charging gun 2 is stronger placed inside the housing 2. This solves the problem of empty space between the housing 1 and one part of the end portion 7 of the charging gun 2 that is shorter than the other.

Preferably the adapter 6 is in form of a grid however the person skilled in the art will know that it may be in any other shape that solves this problem.

Preferably, the connecting means 4 is in the form of an element configured for attaching it to the housing 1 in such a way that it is attached to the cable 5, preferably it is fixedly attached to the cable 5. This connection can be formed by tightening the connecting means 4 to the housing 1 by screws, by glue or in any other possible way that is known for the person skilled in the art.

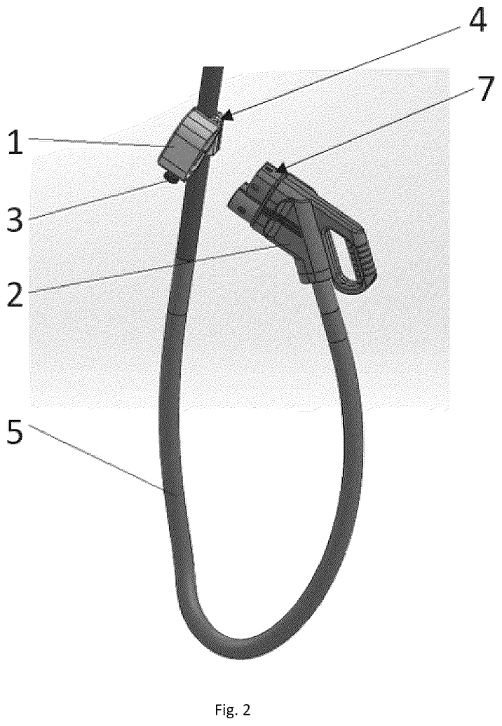

In a second example a device with a charging gun 2 and a cable 5 connected to the charging unit is disclosed. The cable 5 comprising a holder according to the invention is shown in details in FIG. 2. The holder is attached to the cable 5 as previously described.

Such device solves the problem of a need to service the excess of the cable 5, because the holder is mounted directly on the cable 5. The excess of the cable will not lie on the ground what improve safety of the crossing by people and is less vulnerable for any kind of damages which may occur while the cable 5 and/or the charging gun 2 is laying on a ground.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. A holder for a charging gun, comprising:
a housing configured for receiving an end portion of a charging gun such that connector pins located at an end portion of the charging gun are completely covered by the housing of the holder;
a protecting means configured for holding the charging gun in a designated position; and
a connecting means configured for attaching the housing to a cable.

2. The holder according to claim 1, wherein the protecting means is in a form of a blocking pin with a handle, wherein the handle is located on the outer side of the housing.

3. The holder according to claim 1, wherein the housing is configured for receiving the charging gun in the housing by press-fitting.

4. The holder according to claim 1, wherein the protecting means is in a form of a hook attached to the housing, and wherein a corresponding protrusion on a surface of the surface gun is configured to engage the hook.

5. The holder according to claim 1, wherein the housing is made of a non-conductive material.

6. The holder according to claim 1, wherein the housing is made of a polymer.

7. The holder according to claim 1, wherein the housing is inclined relative to the cable at an angle of less than 90°.

8. The holder according to claim 1, further comprising an adapter configured for aligning a position of the charging gun inside the housing.

9. The holder according to claim 8, wherein the adapter is in a form of a grid.

10. The holder according to claim 1, wherein the connecting means is in a form of an element configured for attaching the charging gun to the housing in such a way that it is rigidly attached to the cable.
